(19) United States
(12) Patent Application Publication
(10) Pub. No.: US 2018/0269319 A1
(43) Pub. Date: Sep. 20, 2018

(54) HIGH VOLTAGE DEVICE AND MANUFACTURING METHOD THEREOF

(71) Applicant: RICHTEK TECHNOLOGY CORPORATION, Zhubei City (TW)

(72) Inventors: Kun-Huang Yu, Xinfeng Township (TW); Tsung-Yi Huang, Hsinchu (TW)

(21) Appl. No.: 15/624,646

(22) Filed: Jun. 15, 2017

(30) Foreign Application Priority Data
Mar. 16, 2017 (TW) 106108804
Jun. 6, 2017 (TW) 106118626

(51) Int. Cl. H01L 29/78; H01L 29/423; H01L 29/66

(52) U.S. Cl. CPC H01L 29/7816; H01L 29/66484; H01L 29/66681; H01L 29/4238

(57) ABSTRACT

The invention provides a high voltage device, including: an operation layer, formed on a substrate; a body region and a well, formed in the operation layer to connect the top surface, wherein a PN interface is formed between the body region and the well; a gate, formed on the top surface; a drain and a source, the source formed in a portion of the operation layer in the body region, and the drain formed in a portion of the operation layer in the well; a pseudo-gate, formed on the top surface between the gate and the drain; a first resist protection oxide layer, formed on the gate, the well, and the pseudo-gate; a first conductor layer, formed on the first resist protection oxide layer; a second resist protection oxide layer, formed on the pseudo-gate and the well, the second resist protection oxide layer having no contact with the first resist protection oxide layer; and a second conductor layer, formed on the second resist protection oxide layer.

### CROSS REFERENCE

The present invention claims priority to TW 106108804, filed on Mar. 16, 2017; and TW 106118626, filed on Jun. 6, 2017.

### BACKGROUND OF THE INVENTION

### Field of Invention

The present invention relates to a high voltage device, in particular a high voltage device which includes a pseudo-gate between a gate and a drain, two resist protection oxide layers not in contact with each other, and two conductor layers not in contact with each other to reduce voltage breakdown possibility.

### Description of Related Art

FIG. 1 shows a prior art high voltage device 10. The high voltage device 10 includes: a substrate 11; an operation layer 12, formed on the substrate 11, the operation layer 12 including a body region 13 and a well 14; a gate G, formed on a top surface 121 of the operation layer 12; a source S, formed in a portion of the operation layer 12 in the body region 13; a drain D, formed in a portion of the operation layer 12 in the well 14, the drain D being located between the well 14 and the top surface 121 in a vertical direction; a resist protection oxide RPO, which is a continuous structure formed on a portion of the gate G and on a portion of the well 14, extending to be adjacent to the drain D; a silicon layer Ls, formed on the resist protection oxide RPO, the conductor layer Ls being aligned with the resist protection oxide RPO (i.e., the silicon layer Ls including a same projection area as the resist protection oxide RPO, as viewed from a direction perpendicular to the top surface 121).

FIG. 2 shows an electric field distribution curve C1 in the operation layer 12 of the high voltage device 10 in a non-conductive status. There is a local high electric field peak in the electric field distribution curve C1, and this high electric field peak is likely to cause a voltage breakdown; therefore, the operation voltage range of the high voltage device 10 is quite limited. The scales in the horizontal and vertical coordinates in the figure are for illustrative purpose only, and the numbers can differ in different devices. But in any case, the local high electric field peak limits the operation voltage range of the high voltage device 10.

### SUMMARY OF THE INVENTION

In one perspective, the present invention provides a high voltage device, comprising: a substrate; an operation layer, formed on the substrate in a vertical direction, the operation layer having a top surface opposite to the substrate; a body region having a first conductive type, the body region being formed in the operation layer, and upwardly connecting the top surface; a well, formed in the operation layer and having a second conductive type, the well upwardly connecting the top surface in the vertical direction and connecting the body region at least in a lateral direction perpendicular to the vertical direction, wherein a PN junction is formed between the well and the body region; a gate, formed on the top surface, wherein the PN junction is located right under the gate; a source, formed in a portion of the operation layer in the body region, the source having the second conductive type, the source being in contact with the body region and the top surface; a drain, formed in a portion of the operation layer in the well, the drain having the second conductive type, the drain being in contact with the well and the top surface; a pseudo-gate, formed on the top surface, located between the gate and the drain in the lateral direction; a first resist protection oxide layer, having a first continuous structure which is formed on a portion of the gate, a portion of the well, and a portion of the pseudo-gate, wherein the portion of the first continuous structure on the portion of the well is located between the gate and the pseudo-gate; a first conductor layer, formed on the first resist protection oxide layer; a second resist protection oxide layer, having a second continuous structure which is formed on another portion of the pseudo-gate and another portion of the well, wherein the second resist protection oxide layer does not contact the first resist protection oxide layer, and the portion of the second continuous structure on the another portion of the well is located between the drain and the pseudo-gate; and a second conductor layer, formed on the second resist protection oxide layer, wherein the second conductor layer does not contact the first conductor layer.

In one embodiment, the first conductor layer is electrically connected to the gate.

In one embodiment, the pseudo-gate is synchronously formed in a step of forming the gate, or the second resist protection oxide layer is synchronously formed in a step of forming the first resist protection oxide layer, or the second conductor layer is synchronously formed in a step of forming the first conductor layer.

In one embodiment, the first conductor layer and the second conductor layer are respectively aligned with the first resist protection oxide layer and the second resist protection oxide layer.

In one embodiment, the pseudo-gate does not contact the gate in the lateral direction.

In one embodiment, the second conductor layer is electrically connected to a first predetermined voltage level. In one embodiment, the pseudo-gate is electrically connected to a second predetermined voltage level. In one embodiment, the first predetermined voltage level or the second predetermined voltage level is a ground, an electrical floating level, a voltage level corresponding to the gate, a voltage level corresponding to the drain, or a voltage level corresponding to the source.

In one embodiment, the source has a lateral side which is aligned with a lateral side of the gate, and the drain has a lateral side which is aligned with a lateral side of the second resist protection oxide layer.

In one embodiment, the high voltage device further includes a local oxidation of silicon (LOCOS) structure formed on the top surface, wherein another portion of the gate is formed on the LOCOS structure, and the first continuous structure is formed on the portion of the gate, a portion of the LOCOS structure, the portion of the well, and the portion of the pseudo-gate, wherein the portion of the first continuous structure on the portion of the well is located between the gate and the pseudo-gate.

In one perspective, the present invention provides a manufacturing method of the high voltage device. The manufacturing method includes: providing a substrate; forming an operation layer on the substrate in a vertical direction, the operation layer having a top surface opposite to the substrate; forming a body region having a first conductive type in the operation layer, the body region upwardly connecting the top surface; forming a well having a second conductive type in the operation layer, the well upwardly connecting the top surface in the vertical direction, and connecting the body region at least in a lateral direction perpendicular to the vertical direction, wherein a PN junction is formed between the well and the body region; forming a gate on the top surface, wherein the PN junction is located right under the gate; forming a pseudo-gate on the top surface, the pseudo-gate being away from the gate by a distance; forming a first resist protection oxide layer having a first continuous structure located on a portion of the gate, a portion of the well, and a portion of the pseudo-gate; forming a second resist protection oxide layer having a second continuous structure located on another portion of the pseudo-gate and another portion of the well, wherein the second resist protection oxide layer does not contact the first resist protection oxide layer; forming a first conductor layer on the first resist protection oxide layer; forming a second conductor layer on the second resist protection oxide layer, wherein the second conductor layer does not contact the first conductor layer; forming a source having the second conductive type in a portion of the operation layer in the body region, the source being in contact with the body region and the top surface; and forming a drain having the second conductive type in a portion of the operation layer in the well, the drain being in contact with the well and the top surface; wherein the pseudo-gate is formed between the gate and the drain in the lateral direction; wherein the portion of the first continuous structure on the portion of the well is located between the gate and the pseudo-gate; and wherein the portion of the second continuous structure on the another portion of the well is located between the drain and the pseudo-gate.

The objectives, technical details, features, and effects of the present invention will be better understood with regard to the detailed description of the embodiments below, with reference to the drawings.

### BRIEF DESCRIPTION OF THE DRAWINGS

FIGS. 1 and 2 show a high voltage device and a corresponding electric field distribution in the high voltage device according to a prior art.

FIGS. 3 shows a high voltage device according to one embodiment of the present invention.

FIG. 4 shows two electric field distribution curves respectively according to the prior art high voltage device and the high voltage device of the present invention.

FIGS. 5 and 6 respectively show two high voltage devices according to two embodiments of the present invention.

FIG. 7 shows two impact ionization distributions respectively according to the prior art high voltage device and the high voltage device of the present invention.

FIGS. 8A and 8B a manufacturing method of a high voltage devices according to one embodiment of the present invention.

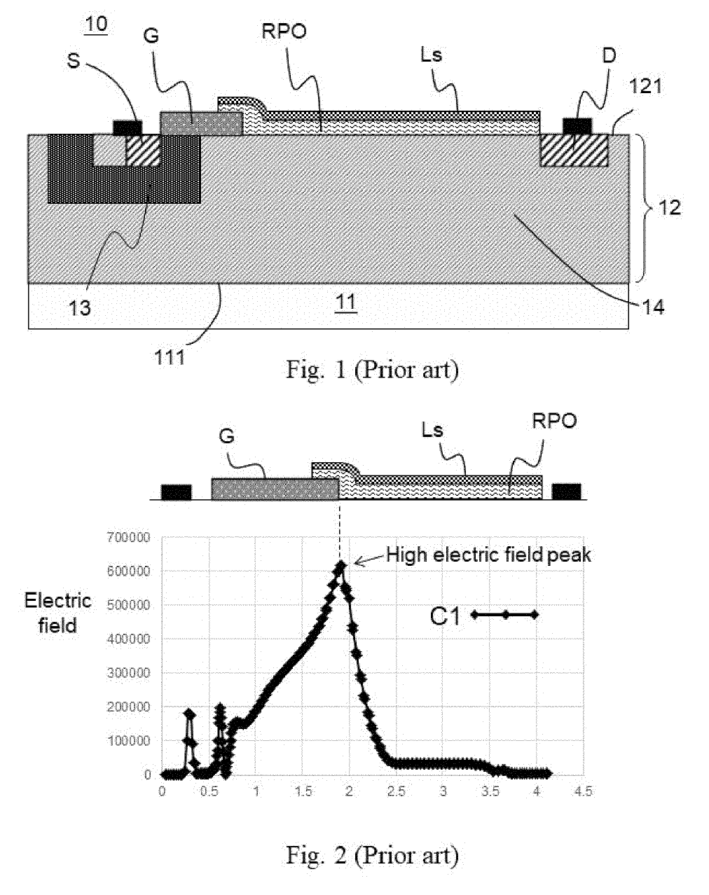

### DESCRIPTION OF THE PREFERRED EMBODIMENTS

The drawings as referred to throughout the description of the present invention are for illustrative purpose only, to show the interrelations between the components, but not drawn according to actual scale.

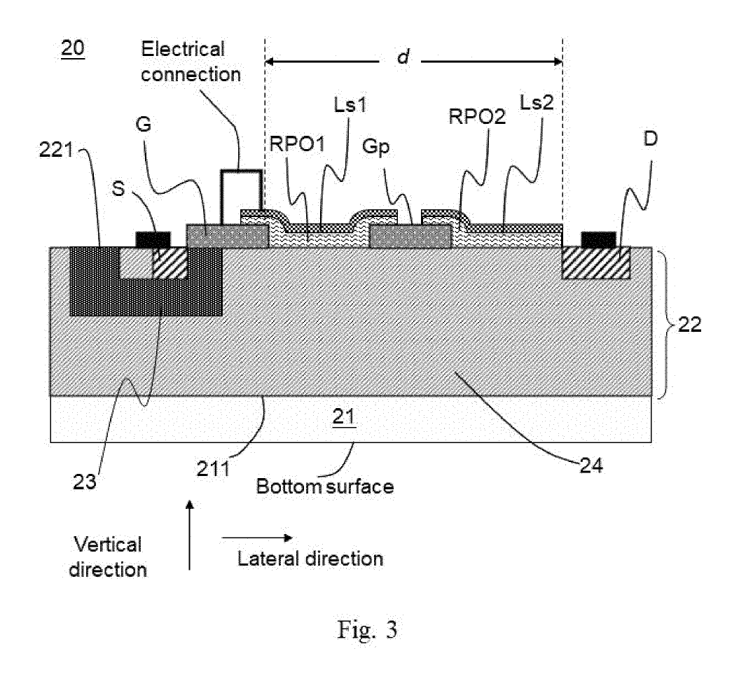

FIG. 3 shows a high voltage device 20 according to one embodiment of the present invention. The high voltage device 20 includes: a substrate 21, including a surface 211; an operation layer 22, formed on and in contact with the surface 211 of the substrate 21 in a vertical direction, the operation layer 22 including a top surface 221 opposite to the substrate 21; a body region 23 having a first conductive type, the body region 23 being formed in the operation layer 22, and upwardly connecting the top surface 22 in the vertical direction; a well 24 having a second conductive type and formed in the operation layer 22, the well 24 upwardly connecting the top surface 221 in the vertical direction and connecting the body region 23 in a lateral direction perpendicular to the vertical direction, wherein a PN junction is formed between the well 24 and the body region 23; a gate G, formed on the top surface 221, wherein the PN junction is located right under the gate G in the vertical direction; a source S having the second conductive type, the source S being formed in a portion of the operation layer 22 in the body region 23, the source S being in contact with the body region 23 and the top surface 221; a drain D having the second conductive type, the drain D being formed in a portion of the operation layer 22 in the well 24, and in contact with the well 24 and the top surface 221; a pseudo-gate Gp, formed on the top surface 221, and located between the gate G and the drain D in a range d in the lateral direction; a first resist protection oxide layer RPO1, having a first continuous structure which is formed on a portion of the gate G, a portion of the well 24, and a portion of the pseudo-gate Gp, wherein the portion of the first continuous structure on the portion of the well 24 is located between the gate G and the pseudo-gate Gp; a first conductor layer Ls1, formed on the first resist protection oxide layer RPO1, wherein in one embodiment, the first conductor layer Ls1 can be optionally coupled to the gate G; a second resist protection oxide layer RPO2, having a second continuous structure which is formed on another portion of the pseudo-gate Gp and another portion of the well 24, wherein the second resist protection oxide layer RPO2 does not contact the first resist protection oxide layer RPO1, and the portion of the second continuous structure on the another portion of the well 24 is located between the drain D and the pseudo-gate Gp; and a second conductor layer Ls2, formed on the second resist protection oxide layer RPO2, wherein the second conductor layer Ls2 does not contact the first conductor layer Ls1. In the context of the present invention, the term “high voltage device” refers to a transistor device whose current inflow terminal may receive an operation voltage higher than 5V during a normal operation. Preferably, in the high voltage device, there is a drift region between the drain and the gate, to separate the drain and the gate. The lateral distance of the drift region can be adjusted according to the operation range of the transistor device.

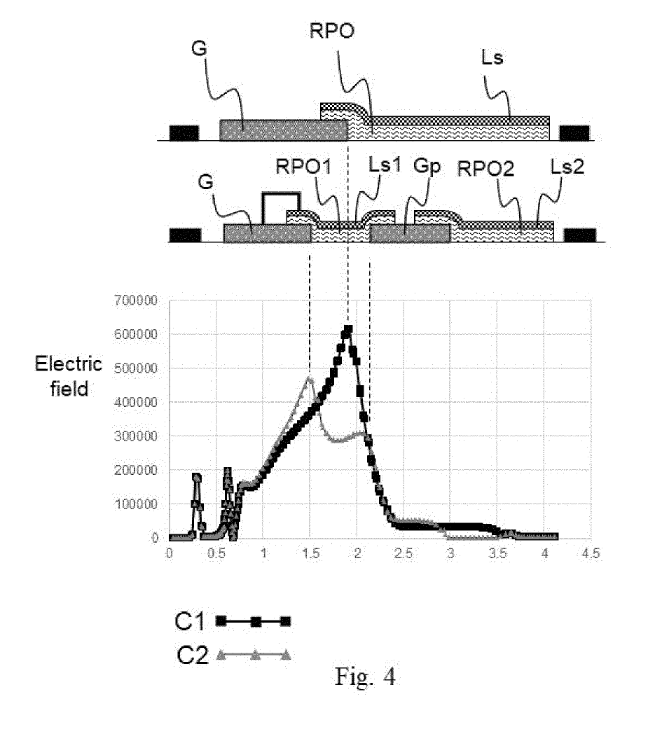

According to the present invention, the electric filed distribution in the operation layer 22 in a non-conductive status of the high voltage device 20, is much smoother than that of the prior art high voltage device 10 which has a local high electric field peak in the operation layer 12. FIG. 4 shows two high voltage devices (partially) respectively according to the prior art and the present invention, wherein only the gate G, the resist protection oxide layer RPO, and the conductor layer Ls in the prior art high voltage device 10 are shown, and only the gate G, the pseudo-gate Gp, the first and second resist protection oxide layer RPO1 and RPO2, and the first and second conductor layers Ls1 and Ls2 in the high voltage device 20 of the present invention are shown. Under the same condition (for example, the same voltage is applied to the drains of the two devices), the local high electric field peak in the electric field distribution curve C1 of the high voltage device 10 is obviously higher than the peaks of the electric field distribution curve C2 of the high voltage device 20 of the present invention. This means that the high voltage device of the present invention has a higher breakdown voltage and there can be applied to a wider application ranges. In comparison with the prior art high voltage device, in a non-conductive status of the high voltage device of the present invention, the pseudo-gate Gp, the first and second resist protection oxide layer RPO1 and RPO2, and the first and second conductor layers Ls1 and Ls2, are capable of adjusting an electron/hole drift distribution in the well, to reduce the possibility of causing the voltage breakdown. Note that the scales in the horizontal and vertical coordinates are for illustrative purpose only, and not to limit the scope of the present invention.

Referring to FIG. 3, the aforementioned vertical direction is an out-of-plane direction of the substrate 21, i.e., a direction perpendicular to a top or bottom surface of the substrate 21. The aforementioned lateral direction is perpendicular to the vertical direction. The lateral direction is the so-called “channel direction” known by the skilled in the art.

In one embodiment, the first conductive type and the second conductive type can respectively be a P-type conductive type and an N-type conductive type. In another embodiment, the first conductive type and the second conductive type can respectively be the N-type conductive type and the P-type conductive type. The PN-junction is formed between the first conductive type impurities of the body region 23 and the second conductive type impurities of the well 24, or, in a boundary between the body region 23 and the well 24. The PN-junction is located right under the gate G, that is, a part of the body region 23 is under the gate G and a part of the well 23 is also under the gate G.

The first continuous structure of the first resist protection oxide layer RPO1 is formed on a portion of the gate G, a portion of the well 24, and a portion of the pseudo-gate Gp. The portion of the first continuous structure on the portion of the well 24 is located between the gate G and the pseudo-gate Gp; the gate G and the pseudo-gate Gp are insulated from one the other by the first resist protection oxide layer RPO1.

The second resist protection oxide layer RPO2 includes a second continuous structure, which is formed on another portion of the top surface of the pseudo-gate Gp and another portion of the well 24. The portion of the second continuous structure on the another portion of the well 24 is located between the drain D and the pseudo-gate Gp; the drain D and the pseudo-gate Gp are insulated from one the other by the second resist protection oxide layer RPO2. Besides, the second resist protection oxide layer RPO2 does not contact the first resist protection oxide layer RPO1.

In one embodiment, the pseudo-gate Gp is not in contact with the gate G in the lateral direction and is not electrically connected with the gate G, and the second conductor layer Ls2 is at an electrically floating level. In another embodiment, the second conductor layer Ls2 can be electrically connected to the gate G. The connection of the second conductor layer Ls2 can be determined, for example, according to the desired electron/hole drift distribution or the electric field distribution in the well 24.

In one embodiment, the pseudo-gate Gp is synchronously formed in a step of forming the gate G, so that no dedicated step is required for forming the pseudo-gate Gp to simplify the manufacturing process, and to reduce manufacturing time and cost.

In one embodiment, the second conductor layer Ls2 is electrically connected to a first predetermined voltage level. In one embodiment, the pseudo-gate Gp is electrically connected to a second predetermined voltage level. In one embodiment, the first predetermined voltage level or the second predetermined voltage level is a ground, an electrical floating level, a voltage level corresponding to the gate, a voltage level corresponding to the drain, or a voltage level corresponding to the source. The first and second predetermined voltage levels can be determined according to different application requirements. In one embodiment, the first and second predetermined voltage levels can be in a range between 0-500 V.

In one embodiment, the first conductor layer Ls1 and the second conductor layer Ls2 are respectively aligned with the first resist protection oxide layer RPO1 and the second resist protection oxide layer RPO2. For example, the same mask used to define and pattern the first resist protection oxide layer RPO1 and the second resist protection oxide layer RPO2, can be used to define and pattern the first conductor layer Ls1 and the second conductor layer Ls2.

In one embodiment, the second resist protection oxide layer RPO2 is synchronously formed in a step of forming the first resist protection oxide layer RPO1, that is, the first resist protection oxide layer RPO1 and the second resist protection oxide layer RPO2 are defined and patterned by one same mask; the deposition, lithography and etch steps of the first resist protection oxide layer RPO1 and the second resist protection oxide layer RPO2 are the same steps. In one embodiment, the second conductor layer Ls2 is synchronously formed in a step of forming the first conductor layer Ls1, and the first conductor layer Ls1 and the second conductor layer Ls2 are respectively defined and patterned on the first resist protection oxide layer RPO1 and the second resist protection oxide layer RPO2, by the same mask of forming the first resist protection oxide layer RPO1 and the second resist protection oxide layer RPO2; the deposition, lithography and etch steps of the first conductor layer Ls1 and the second conductor layer Ls2 are the same steps. In this embodiment, there is only one mask required for forming the first and second resist protection oxide layers RPO1 and RPO2, and the first and second conductor layer Ls1 and Ls2.

In one embodiment, each of the first and second conductor layers Ls1 and Ls2 comprises silicon material. In one embodiment, the first and second conductor layers Ls1 and Ls2 are formed on the first and second resist protection oxide layers RPO1 and RPO2 by a self-aligned process, and the source S and the drain D are also formed a self-aligned process. More specifically, in one embodiment, after the operation layer 22 is formed on the substrate 21, and the body region 23 and the well 24 are formed in the operation layer 22, the gate G and the pseudo-gate Gp are formed by deposition, lithography and etch steps, and an oxide layer and a silicon layer are sequentially formed on the top surface 221 of the operation layer 22. Next, with one same mask (such as a photoresist mask patterned by a lithography process), the silicon layer is etched to form the first and second conductor layers Ls1 and Ls2, and the oxide layer is etched to form the first and second resist protection oxide layers RPO1 and RPO2. Thus, the first and second conductor layers Ls1 and Ls2 are respectively aligned with the first and second resist protection oxide layers RPO1 and RPO2. Next, the source S and the drain D are implanted by an implantation step according to a pattern of at least the gate G and the second resist protection oxide layer RPO2, such that a lateral side of the source S is aligned with a lateral side of the gate G, and a lateral side of the drain D is aligned with a lateral side of the second resist protection oxide layer RPO2. Note that, if the first and second conductor layers Ls1 and Ls2 are made of a material other than silicon, the self-aligned process is still applicable.

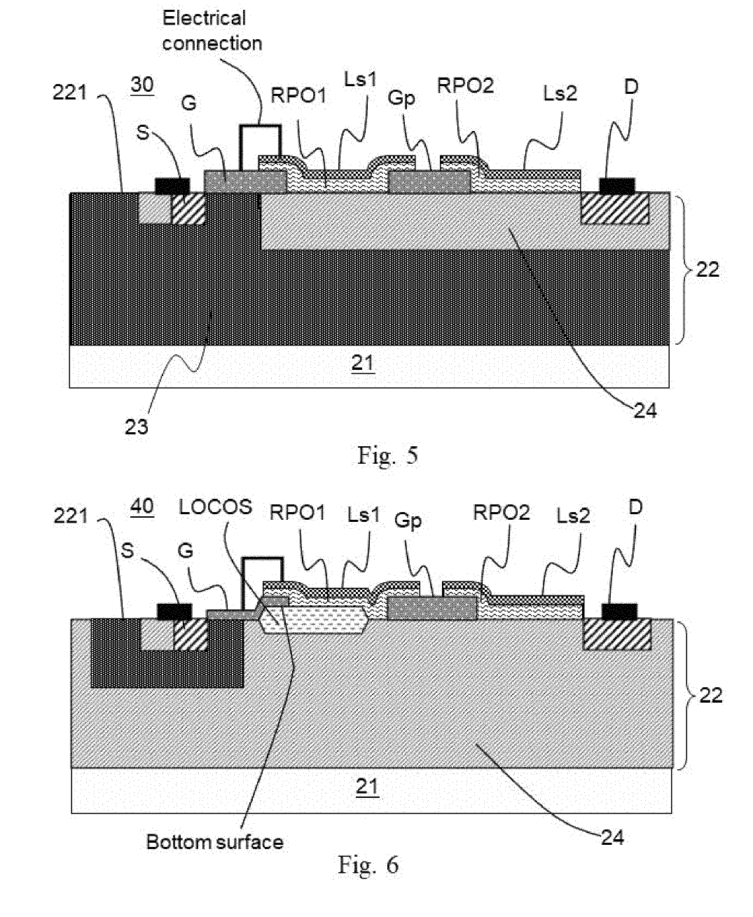

FIG. 5 shows a high voltage device 30 according to one embodiment of the present invention. In the high voltage device 30, the body region 23 is located on the substrate 21. The well 24 is located in the body region 23, between the drain D and the body region 23. The other components of the high voltage device 30 operate similarly to the embodiment of FIG. 3.

FIG. 6 shows a high voltage device 40 according to one embodiment of the present invention. The high voltage device 40 includes a local oxidation of silicon structure LOCOS, formed on the top surface 221. As shown in FIG. 6, a portion of the gate G which is not on the body region 23 is formed on the local oxidation of silicon structure LOCOS. The first continuous structure of the first resist protection oxide layer RPO1 is formed on the portion of the gate G, a portion of the local oxidation of silicon structure LOCOS, the portion of the well 24, and the portion of the pseudo-gate Gp. The portion of the first continuous structure on the portion of the well 24 is located between the gate G and the pseudo-gate Gp.

In one embodiment, the local oxidation of silicon structure LOCOS in the high voltage device can be replaced by a shallow trench isolation (not shown), which is formed on the top surface 221. A portion of the gate G which is not on the body region 23 is formed on the shallow trench isolation. The first continuous structure of the first resist protection oxide layer RPO1 is formed on the portion of the gate G, a portion of the shallow trench isolation, the portion of the well 24, and the portion of the pseudo-gate Gp. The portion of the first continuous structure on the portion of the well 24 is located between the gate G and the pseudo-gate Gp.

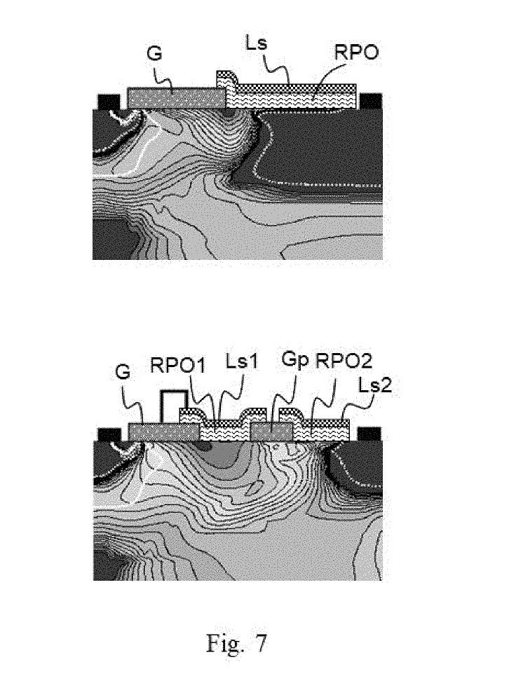

Please refer to FIG. 7. The upper part and the lower part of FIG. 7 respectively show the impact ionization distributions of the prior art and the present invention, wherein the distribution density of the gradient curves represents the tendency of increase (or tendency of decrease) of the impact ionization. The distribution density of the gradient curves corresponds to the distribution of the electric field. The impact ionization distribution according to the prior art shown on the upper part of FIG. 7 shows a high distribution density in the operation layer close to right side of the gate G, corresponding to the local high electric field peaks shown in FIGS. 2 and 4; the ionization tendency is very high here, which is one major cause for voltage breakdown. The impact ionization distribution according to the present invention shown on the lower part of FIG. 7 shows a lower distribution density than the prior art at the same location. Referring to the curve C2 as shown in FIG. 4, the electric field close to the right side of the gate G is much more lower than the prior art. Therefore, under the same condition, the high voltage device of the present invention can operate in a wider voltage range that the prior art, without causing the voltage breakdown.

According to simulation analysis, the breakdown voltage according to the high voltage device of the present invention is at least 47% higher than the high voltage device of the prior art. Therefore, the high voltage device of the present invention is superior to the high voltage device of the prior art.

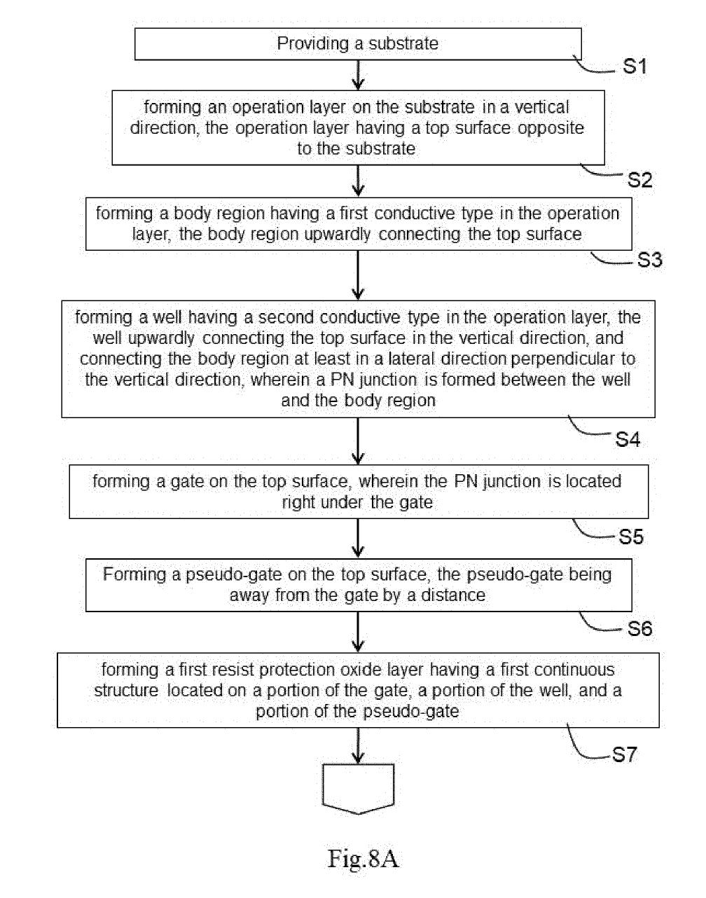

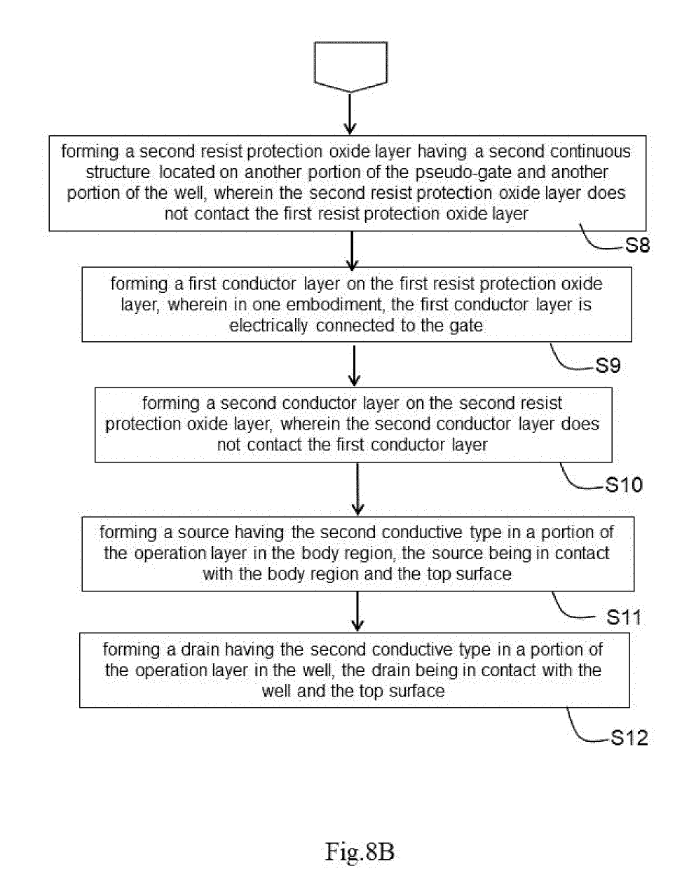

FIGS. 8A and 8B show a method for manufacturing a high voltage device according to one perspective of the present invention. The manufacturing method includes: providing a substrate (S1); forming an operation layer on the substrate in a vertical direction, the operation layer having a top surface opposite to the substrate (S2); forming a body region having a first conductive type in the operation layer, the body region upwardly connecting the top surface (S3); forming a well having a second conductive type in the operation layer, the well upwardly connecting the top surface in the vertical direction, and connecting the body region at least in a lateral direction perpendicular to the vertical direction, wherein a PN junction is formed between the well and the body region (S4); forming a gate on the top surface, wherein the PN junction is located right under the gate (S5); forming a pseudo-gate on the top surface, the pseudo-gate being away from the gate by a distance (S6); forming a first resist protection oxide layer having a first continuous structure located on a portion of the gate, a portion of the well, and a portion of the pseudo-gate (S7); forming a second resist protection oxide layer having a second continuous structure located on another portion of the pseudo-gate and another portion of the well, wherein the second resist protection oxide layer does not contact the first resist protection oxide layer (S8); forming a first conductor layer on the first resist protection oxide layer, wherein in one embodiment, the first conductor layer is electrically connected to the gate (S9); forming a second conductor layer on the second resist protection oxide layer, wherein the second conductor layer does not contact the first conductor layer (S10); forming a source having the second conductive type in a portion of the operation layer in the body region, the source being in contact with the body region and the top surface (S11); and forming a drain having the second conductive type in a portion of the operation layer in the well, the drain being in contact with the well and the top surface (S12); wherein the pseudo-gate is formed between the gate and the drain in the lateral direction; wherein the portion of the first continuous structure on the portion of the well is located between the gate and the pseudo-gate; and wherein the portion of the second continuous structure on the another portion of the well is located between the drain and the pseudo-gate.

The steps of the above manufacturing method do not necessarily have to follow the described order. For example, the steps S7 and S8 can be performed concurrently or by a different order; the steps S9 and S10 can be performed concurrently or by a different order; and the steps S11 and S12 can be performed concurrently or by a different order.

In one embodiment, the steps S7-S10 are performed according to a self-aligned process which includes the following steps: depositing an oxide layer; depositing a conductor layer on the oxide layer; with one same mask (such as a photoresist mask patterned by a lithography process), the conductor layer is etched by an etchant to form the first and second conductor layers, and the oxide layer is etched by a different etchant to form the first and second resist protection oxide layers.

In one embodiment, the steps S11-S12 are performed according to a self-aligned process which includes the following steps: implanting impurities to form the source and the drain according to a pattern of at least the gate and the second resist protection oxide layer, such that a lateral side of the source is aligned with a lateral side of the gate, and a lateral side of the drain is aligned with a lateral side of the second resist protection oxide layer. If it is not required for the source and the drain to be self aligned, the steps S11-S12 do not have to be performed after the steps S7-S10.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention; for example, there may be additional layers or regions inserted between two layers or regions shown to be in direct connection in the embodiments, as long as such inserted layers or regions do not affect the primary function of the device and the device can still achieve the objective of the present invention. Besides, an embodiment or a claim of the present invention does not need to attain or include all the objectives, advantages or features described in the above. The abstract and the title are provided for assisting searches and not to be read as limitations to the scope of the present invention. It is not limited for each of the embodiments described hereinbefore to be used alone; under the spirit of the present invention, two or more of the embodiments described hereinbefore can be used in combination. For example, two or more of the embodiments can be used together, or, apart of one embodiment can be used to replace a corresponding part of another embodiment. All such modifications and variations should fall in the scope of the present invention.

1. A high voltage device, comprising:
a substrate;
an operation layer, formed on the substrate in a vertical direction, the operation layer having a top surface opposite to the substrate;
a body region having a first conductive type, the body region being formed in the operation layer, and upwardly connecting the top surface;
a well, formed in the operation layer and having a second conductive type, the well upwardly connecting the top surface in the vertical direction and connecting the body region at least in a lateral direction perpendicular to the vertical direction, wherein a PN junction is formed between the well and the body region;
a gate, formed on the top surface, wherein the PN junction is located right under the gate;
a source, formed in the body region, the source having the second conductive type, the source being in contact with the top surface;
a drain, formed in the well, the drain having the second conductive type, the drain being in contact with the top surface;
a pseudo-gate, formed on the top surface, located between the gate and the drain in the lateral direction;
a first resist protection oxide layer, having a first continuous structure which has a first portion formed on and contacting the gate, a second portion on and contacting the well, and a third portion on and contacting the pseudo-gate, wherein the second portion of the first continuous structure on the well is located between the gate and the pseudo-gate;
a first conductor layer, formed on the first resist protection oxide layer;
a second resist protection oxide layer, having a second continuous structure which has a fourth portion formed on and contacting the pseudo-gate and a fifth portion formed on and contacting the well, wherein the second resist protection oxide layer does not contact the first resist protection oxide layer, and the fifth portion of the second continuous structure on the well is located between the drain and the pseudo-gate; and
a second conductor layer, formed on the second resist protection oxide layer, wherein the second conductor layer does not contact the first conductor layer;
wherein the source has a lateral side which is aligned with a lateral side of the gate, and the drain has a lateral side which is aligned with a lateral side of the second resist protection oxide layer.

2. The high voltage device of claim 1, wherein the first conductor layer is electrically connected to the gate.

3. The high voltage device of claim 1, wherein the pseudo-gate is synchronously formed in a step of forming the gate, or the second resist protection oxide layer is synchronously formed in a step of forming the first resist protection oxide layer, or the second conductor layer is synchronously formed in a step of forming the first conductor layer.

4. The high voltage device of claim 1, wherein the second conductor layer has a voltage level which is floating.

5. The high voltage device of claim 1, wherein the first conductor layer and the second conductor layer are respectively aligned with the first resist protection oxide layer and the second resist protection oxide layer.

6. The high voltage device of claim 1, wherein the pseudo-gate does not contact the gate in the lateral direction.

7. The high voltage device of claim 1, wherein the second conductor layer is electrically connected to a first predetermined voltage level, and the pseudo-gate is electrically connected to a second predetermined voltage level.

8. The high voltage device of claim 7, wherein the first predetermined voltage level or the second predetermined voltage level is a ground, an electrical floating level, a gate voltage level, a drain voltage level, or a source voltage level.

9. (canceled)

10. The high voltage device of claim 1, further comprising a local oxidation of silicon (LOCOS) structure formed on the top surface, wherein another portion of the gate is formed on the LOCOS structure, and the first continuous structure is formed on the portion of the gate, a portion of the LOCOS structure, the portion of the well, and the portion of the pseudo-gate, wherein the portion of the first continuous structure on the portion of the well is located between the gate and the pseudo-gate.

11. A method for manufacturing high voltage device, comprising:
providing a substrate;
forming an operation layer on the substrate in a vertical direction, the operation layer having a top surface opposite to the substrate;
forming a body region having a first conductive type in the operation layer, the body region upwardly connecting the top surface;
forming a well having a second conductive type in the operation layer, the well upwardly connecting the top surface in the vertical direction, and connecting the body region at least in a lateral direction perpendicular to the vertical direction, wherein a PN junction is formed between the well and the body region;
forming a gate on the top surface, wherein the PN junction is located right under the gate;
forming a pseudo-gate on the top surface, the pseudo-gate being away from the gate by a distance;
forming a first resist protection oxide layer having a first continuous structure, wherein the first continuous structure includes a first portion located on the gate, a second portion on and contacting the well, and a third portion on and contacting the pseudo-gate;
forming a second resist protection oxide layer having a second continuous structure, wherein the second continuous structure includes a fourth portion located on and contacting a the pseudo-gate and a fifth portion on and contacting the well, wherein the second resist protection oxide layer does not contact the first resist protection oxide layer;
forming a first conductor layer on the first resist protection oxide layer;
forming a second conductor layer on the second resist protection oxide layer, wherein the second conductor layer does not contact the first conductor layer;
forming a source having the second conductive type in the body region, the source being in contact with the top surface; and
forming a drain having the second conductive type in the well, the drain being in contact with the top surface;
wherein the pseudo-gate is formed between the gate and the drain in the lateral direction; wherein the second portion of the first continuous structure on the well is located between the gate and the pseudo-gate; and wherein the fifth portion of the second continuous structure on the well is located between the drain and the pseudo-gate;
wherein the source and the drain are formed by an implantation according to a pattern of at least the gate and the second resist protection oxide layer, such that the source has a lateral side which is aligned with a lateral side of the gate, and the drain has a lateral side which is aligned with a lateral side of the second resist protection oxide layer.

12. The manufacturing method of claim 11, wherein the first conductor layer is electrically connected to the gate.

13. The manufacturing method of claim 11, wherein the pseudo-gate is synchronously formed in a step of forming the gate, or the second resist protection oxide layer is synchronously formed in a step of forming the first resist protection oxide layer, or the second conductor layer is synchronously formed in a step of forming the first conductor layer.

14. The manufacturing method of claim 11, wherein the second conductor layer has a voltage level which is floating.

15. The manufacturing method of claim 11, wherein the first conductor layer, the second conductor layer, the first resist protection oxide layer and the second resist protection oxide layer are etched according to one same mask such that the first conductor layer and the second conductor layer are respectively aligned with the first resist protection oxide layer and the second resist protection oxide layer.

16. The manufacturing method of claim 11, wherein the pseudo-gate does not contact the gate in the lateral direction.

17. The manufacturing method of claim 11, wherein the second conductor layer is electrically connected to a first predetermined voltage level, and the pseudo-gate is electrically connected to a second predetermined voltage level.

18. The manufacturing method of claim 17, wherein the first predetermined voltage level or the second predetermined voltage level is a ground, an electrical floating level, a gate voltage level, a drain voltage level, or a source voltage level.

19. (canceled)

20. The manufacturing method of claim 11, further comprising: forming a local oxidation of silicon (LOCOS) structure on the top surface, wherein another portion of the gate is formed on the LOCOS structure, and the first continuous structure is formed on the portion of the gate, a portion of the local oxidation of silicon, the portion of the well, and the portion of the pseudo-gate, wherein the portion of the first continuous structure on the portion of the well is located between the gate and the pseudo-gate.
